(19) United States
(12) Patent Application Publication
(10) Pub. No.: US 2017/0077378 A1
(43) Pub. Date: Mar. 16, 2017

(54) THERMOELECTRIC GENERATOR

(71) Applicant: FUJITSU LIMITED, Kawasaki-shi (JP)

(72) Inventors: John David Baniecki, Zama (JP); Hideyuki AMADA, Atsugi (JP); Yoshihiko Imanaka, Atsugi (JP)

(73) Assignee: FUJITSU LIMITED, Kawasaki-shi (JP)

(21) Appl. No.: 15/259,323

(22) Filed: Sep. 8, 2016

(30) Foreign Application Priority Data
Sep. 11, 2015 (JP) 2015-179871

(51) Int. Cl. H01L 35/32; H01L 35/22

(52) U.S. Cl. CPC H01L 35/32; H01L 35/22

(57) ABSTRACT

A thermoelectric generator includes: a substrate; a thermoelectric conversion film on the substrate; a thermally insulating film that covers the thermoelectric conversion film; a first heat transfer material that transfers a first heat above the thermally insulating film to a first portion of the thermoelectric conversion film; and a second heat transfer material that transfers a second heat below the substrate to a second portion of the thermoelectric conversion film, the second portion being separated from the first portion.

### CROSS-REFERENCE TO RELATED APPLICATION

This application is based upon and claims the benefit of priority of the prior Japanese Patent Application No. 2015-179871, filed on Sep. 11, 2015, the entire contents of which are incorporated herein by reference.

### FIELD

The embodiments discussed herein are directed to a thermoelectric generator.

### BACKGROUND

In recent years, from a point of view of reduction in carbon dioxide (CO₂) and environmental protection, a thermoelectric generator is attracting attention as a clean electric power generator. By using the thermoelectric generator, thermal energy which has been wasted so far can be reused by being converted into electrical energy. In theory, the thermoelectric generator can generate electricity at any place in which a temperature gradient exists.

However, a conventional thermoelectric generator is difficult to be miniaturized, and due to its structural constraint, available application thereof is limited.

Patent Literature 1: Japanese Laid-Open Patent Publication No. 2005-277343

Patent Literature 2: Japanese Laid-Open Patent Publication No. 2010-95688

### SUMMARY

According to an aspect of the embodiments, a thermoelectric generator includes: a substrate; a thermoelectric conversion film on the substrate; a thermally insulating film that covers the thermoelectric conversion film; a first heat transfer material that transfers a first heat above the thermally insulating film to a first portion of the thermoelectric conversion film; and a second heat transfer material that transfers a second heat below the substrate to a second portion of the thermoelectric conversion film, the second portion being separated from the first portion.

According to another aspect of the embodiments, a thermoelectric generator includes: a substrate; couples of p-type thermoelectric conversion films and n-type thermoelectric conversion films on the substrate; a thermally insulating film that covers the p-type thermoelectric conversion films and the n-type thermoelectric conversion films; a first heat transfer material that transfers a first heat above the thermally insulating film to first portions of the p-type thermoelectric conversion films and the n-type thermoelectric conversion films; and a second heat transfer material that transfers a second heat below the substrate to second portions of the p-type thermoelectric conversion films and the n-type thermoelectric conversion films, each of the second portions being separated from each of the first portions. The p-type thermoelectric conversion film and the n-type thermoelectric conversion film in each of the couple are in contact with each other at a position right below the first heat transfer material. Between the adjacent two couples, the p-type thermoelectric conversion film in one of the two couples and the n-type thermoelectric conversion film in the other one of the two couples are in contact with each other. The couples form a composite structure of the p-type thermoelectric conversion films and the n-type thermoelectric conversion films connected in series.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1A and FIG. 1B are plan views each illustrating a configuration of a thermoelectric generator according to an embodiment;

FIG. 2A to FIG. 2C are cross-sectional views each illustrating a configuration of the thermoelectric generator according to the embodiment;

FIG. 3 is a view illustrating a function of the thermoelectric generator according to the embodiment;

FIG. 4 is a view illustrating a circuit including the thermoelectric generator according to the embodiment and a load;

FIG. 5 is a view illustrating an open circuit including the thermoelectric generator according to the embodiment; and

FIG. 6 is a view illustrating a closed circuit including the thermoelectric generator according to the embodiment.

### DESCRIPTION OF EMBODIMENTS

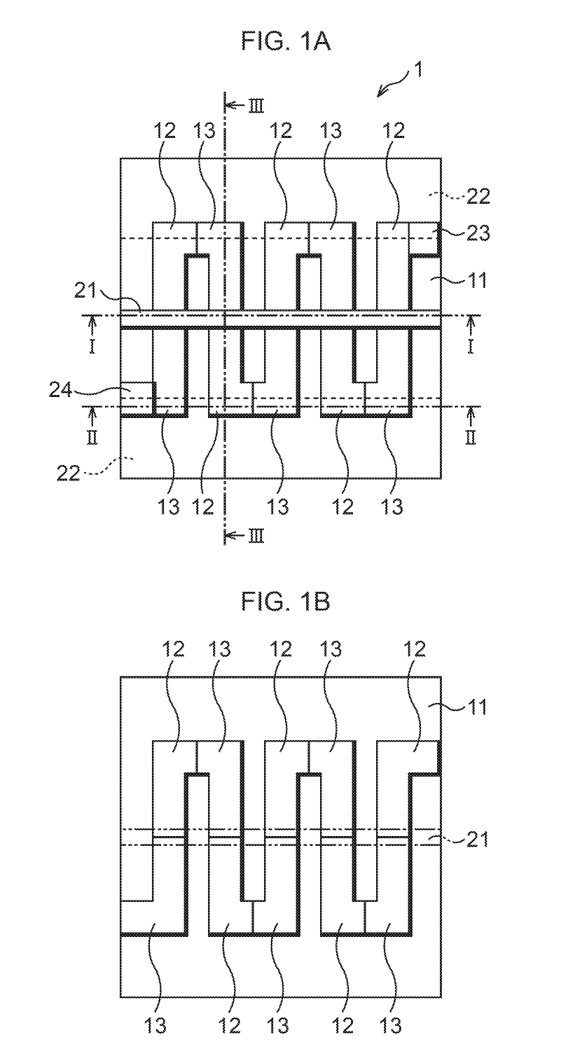

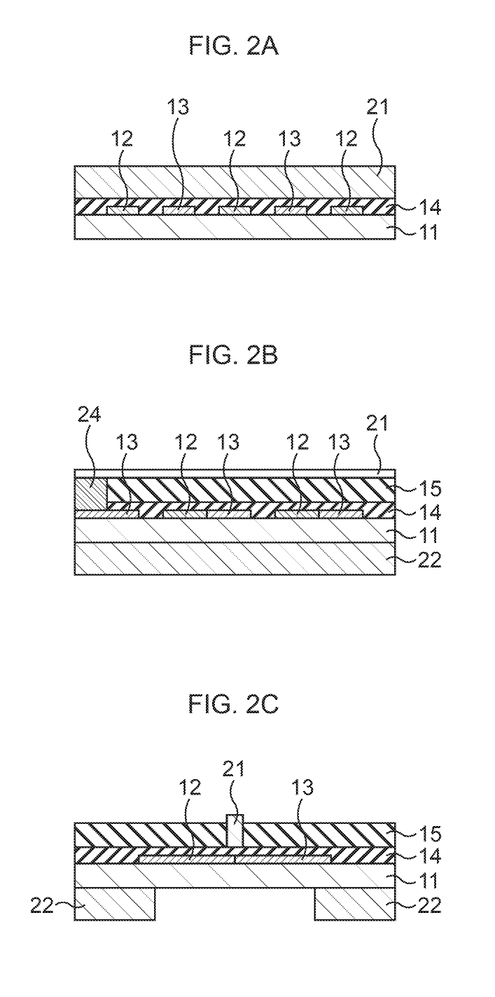

Hereinafter, embodiments will be concretely described while referring to the attached drawings. The present embodiment is an example of a thermoelectric generator. FIG. 1A and FIG. 1B are plan views each illustrating a configuration of the thermoelectric generator according to the embodiment. FIG. 1A mainly illustrates a positional relationship between thermoelectric conversion films and heat transfer materials, and FIG. 1B mainly illustrates a positional relationship of the thermoelectric conversion films. FIG. 2A to FIG. 2C are cross-sectional views each illustrating a configuration of the thermoelectric generator according to the embodiment. FIG. 2A illustrates a cross section taken along a line I-I in FIG. 1A, FIG. 2B illustrates a cross section taken along a line II-II in FIG. 1A, and FIG. 2C illustrates a cross section taken along a line III-III in FIG. 1A.

A thermoelectric generator 1 according to the embodiment includes a substrate 11, p-type thermoelectric conversion films 12 and n-type thermoelectric conversion films 13 on the substrate 11, and a thermally insulating film 15 that covers the p-type thermoelectric conversion films 12 and the n-type thermoelectric conversion films 13. The thermoelectric generator 1 further includes a heat transfer material 21 that transfers a first heat above the thermally insulating film 15 to respective first portions of the p-type thermoelectric conversion films 12 and the n-type thermoelectric conversion films 13, a heat transfer material 22 that transfers a second heat below the substrate 11 to respective second portions of the p-type thermoelectric conversion films 12 and the n-type thermoelectric conversion films 13, the second portion being separated from the respective first portions, and an electrically insulating film 14 that covers the p-type thermoelectric conversion films 12 and the n-type thermoelectric conversion films 13 at a position under the thermally insulating film 15. In FIG. 1A and FIG. 1B, the electrically insulating film 14 and the thermally insulating film 15 are omitted.

The p-type thermoelectric conversion films 12 and the n-type thermoelectric conversion films 13 are included in couples, and are alternately and electrically connected in series. The composite structure of the films 12 and 13 connected in series meanders regularly in planar view, and the heat transfer material 21 extends so as to intersect the composite structure of the films 12 and 13. The p-type thermoelectric conversion film 12 and the n-type thermoelectric conversion film 13 are in contact with each other at a position right below the heat transfer material 21, and the p-type thermoelectric conversion film 12 and the n-type thermoelectric conversion film 13 are in contact with each other also at a position at which the meandering direction is reversed. Thus, the p-type thermoelectric conversion films 12 and the n-type thermoelectric conversion films 13 are alternately disposed along the extending direction of the heat transfer material 21, in which there are couples of a p-type thermoelectric conversion film 12 and a n-type thermoelectric conversion film 13 in contact with each other, on both sides of the heat transfer material 21 in planar view. The p-type thermoelectric conversion film 12 on one side of the heat transfer material 21 is in contact with the n-type thermoelectric conversion film 13 on the other side of the heat transfer material 21 at a position right below the heat transfer material 21, and the n-type thermoelectric conversion film 13 on the one side of the heat transfer material 21 is in contact with the p-type thermoelectric conversion film 12 on the other side of the heat transfer material 21 at a position right below the heat transfer material 21. A pad 23 is disposed on the p-type thermoelectric conversion film 12 at one end of the composite structure, and a pad 24 is disposed on the n-type thermoelectric conversion film 13 at the other end of the composite structure.

In the present embodiment, the heat transfer material 21 and two heat transfer materials 22 extend in the same direction, in which the heat transfer material 21 is between the two heat transfer materials 22 and a position of each of the heat transfer materials 22 is overlapped with the position at which the meandering direction of the composite structure is reversed in planar view. There is no need that the two heat transfer materials 22 are completely divided, and they may also be integrated at a position at which they do not overlap with the heat transfer material 21 in planar view, for example.

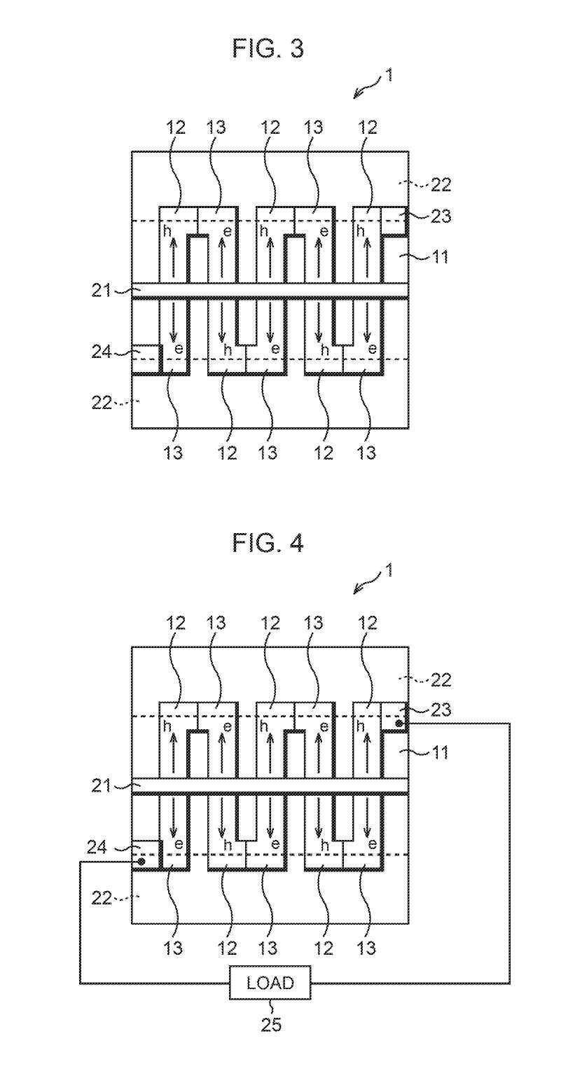

In the present embodiment, when a temperature above the thermally insulating film 15 is higher than a temperature below the substrate 11, a hole (h) moves from a portion (first portion) below the heat transfer material 21 toward a portion (second portion) above the heat transfer material 22 in the p-type thermoelectric conversion film 12, and an electron (e) moves from a portion (first portion) below the heat transfer material 21 toward a portion (second portion) above the heat transfer material 22 in the n-type thermoelectric conversion film 13, as illustrated in FIG. 3. Since the p-type thermoelectric conversion films 12 and the n-type thermoelectric conversion films 13 are electrically connected in series as described above, a current which flows in the same direction among the p-type thermoelectric conversion films 12 and n-type thermoelectric conversion films 13 are generated. The current can be extracted from the pad 23 and the pad 24.

Accordingly, even if a thermoelectric generator in bulk are not used, a current derived from the temperature gradient between the temperature above the thermally insulating film 15 and the temperature below the substrate 11 can be obtained. Therefore, it is possible to realize significant reduction in thickness, and an installable range can be largely widened, when compared to a conventional device. For example, it becomes possible to easily perform generation of electricity using a body temperature, which is quite difficult in a conventional thermoelectric generator, and the thermoelectric generator according to the embodiment can also be used for generation of electricity for a cardiac pacemaker, for example.

A material of the heat transfer material 21 is not particularly limited, and copper (Cu) is preferable for the material. This is because Cu enables easy film formation and has high thermal conductivity. A stack of a Cr film and an Au film on a fluorocarbon resin may be used as the heat transfer material 21. A material of the heat transfer material 22 is not particularly limited, and Cu is preferable for the material. A material of the p-type thermoelectric conversion film 12 is not particularly limited, and LaₐSr₁₋ₐCoO₃ (0<a≦1), La_{b}Ca_{1-b}CoO₃ (0<b≦1), or LaMnO₃ may be used, for example. A material of the n-type thermoelectric conversion film 13 is not particularly limited, and Sr_{c}La_{1-c}TiO₃ (0<c<1), or Sr_{d}Nb_{1-d}TiO₃ (0<d<1) may be used, for example. For example, a combination of a La_{0.89}Sr_{0.11}CoO₃ film as the p-type thermoelectric conversion film 12 and a Sr_{0.95}La_{0.05}TiO₃ film as the n-type thermoelectric conversion film 13 may be used. A combination of a La_{0.89}Ca_{0.11}CoO₃ film as the p-type thermoelectric conversion film 12 and a Sr_{0.95}Nb_{0.05}TiO₃ film as the n-type thermoelectric conversion film 13 may be also used. A combination of a La_{0.90}Sr_{0.10}CoO₃ film as the p-type thermoelectric conversion film 12 and a Sr_{0.93}Nb_{0.07}TiO₃ film as the n-type thermoelectric conversion film 13 may be also used. A material of the insulating film 14 is not particularly limited, and SiO₂, Si₃N₄, or SrTiO₃ may be used for the material, for example. A material of the thermally insulating film 15 is not particularly limited, and a molding resin may be used for the material, for example.

In the present embodiment, each of the portion right below the heat transfer material 21 of the p-type thermoelectric conversion film 12, and the portion right below the heat transfer material 21 of the n-type thermoelectric conversion film 13 is an example of the first portion, and each of the portion right above the heat transfer material 22 of the p-type thermoelectric conversion film 12, and the portion right above the heat transfer material 22 of the n-type thermoelectric conversion film 13 is an example of the second portion. The number of the p-type thermoelectric conversion film(s) 12 and the n-type thermoelectric conversion film(s) 13 is not necessarily two or more. The number of the p-type thermoelectric conversion film 12 or the n-type thermoelectric conversion film 13 may be one. It is possible to obtain a current also in this case, since the hole or the electron moves between the first portion and the second portion of the p-type thermoelectric conversion film 12 or the n-type thermoelectric conversion film 13 in accordance with the temperature gradient.

Next, performance of the thermoelectric generator 1 will be described. Here, it is assumed that thermal conductance and electrical conductance of the substrate 11 can be ignored, and a load 25 is connected between the pad 23 and the pad 24, as illustrated in FIG. 4. When quantity of heat which flows in the thermoelectric generator 1 is denoted by Q_{H}, current which flows through the load 25 is denoted by I, electrical resistance of the load 25 is denoted by R_{L}, and thermoelectric conversion efficiency is denoted by η, the following expression (1) is satisfied.

[Mathematical expression 1]

$$η = \frac{Power to load}{Thermal Power Input} = \frac{{I}^{2} {R}_{L}}{{Q}_{H}} \qquad ( 1 )$$

When a temperature above the heat transfer material 21 is denoted by T_{H}, a gradient between the temperature T_{H} and a temperature below the substrate 11 is denoted by ΔT, internal resistance of the thermoelectric generator 1 is denoted by R, a ratio of the resistance R_{L} to the internal resistance R (R_{L}/R) is denoted by μ, and a figure of merit is denoted by Z, the thermoelectric conversion efficiency η may also be represented by the following expression (2).

[Mathematical expression 2]

$$η - \frac{μ Δ T}{( 1 + μ ) {T}_{H} + \frac{{( 1 + μ )}^{2}}{Z} - Δ T \text{/} 2} \qquad ( 2 )$$

When the number of couples of the p-type thermoelectric conversion films 12 and the n-type thermoelectric conversion films 13 is denoted by N, thermal conductance of the thermoelectric generator 1 is denoted by K, and an effective Seebeck coefficient of one couple of the p-type thermoelectric conversion film 12 and the n-type thermoelectric conversion film 13 is Seebeck a, the figure of merit Z is represented by the following expression (3).

[Mathematical expression 3]

$$Z = \frac{{N}^{2} {α}^{2}}{KR} \qquad ( 3 )$$

The thermal conductance K is the sum of thermal conductance Kₚ of the p-type thermoelectric conversion film 12 and thermal conductance Kₙ of the n-type thermoelectric conversion film 13. Further, when thermal conductivities of the p-type thermoelectric conversion film 12 and the n-type thermoelectric conversion film 13 are denoted by Kₚ and Kₙ, respectively, cross sectional areas of the films 12 and 13 are denoted by Aₚ and Aₙ, respectively, and lengths of the films 12 and 13 are denoted by Lₚ and Lₙ, respectively, the thermal conductance K is represented by the following expression (4).

[Mathematical expression 4]

$$K = {K}_{p} + {K}_{n} = N ( {κ}_{p} \frac{{A}_{p}}{{L}_{p}} + {κ}_{n} \frac{{A}_{n}}{{L}_{n}} ) \qquad ( 4 )$$

The internal resistance R is the sum of internal resistance Rₚ of the p-type thermoelectric conversion film 12 and internal resistance Rₙ of the n-type thermoelectric conversion film 13. Further, when conductivities of the p-type thermoelectric conversion film 12 and the n-type thermoelectric conversion film 13 are denoted by σₚ and σₙ, respectively, the internal resistance R is represented by the following expression (5).

[Mathematical expression 5]

$$R = {R}_{p} + {R}_{N} = N [ ( {( {σ}_{p} \frac{{A}_{p}}{{L}_{p}} )}^{- 1} + {( {σ}_{n} \frac{{A}_{n}}{{L}_{n}} )}^{- 1} ] \qquad ( 5 )$$

The effective Seebeck coefficient α is represented by the following expression (6).

[Mathematical expression 6]

$$α = \frac{1}{{T}_{H} - {T}_{C}} {\int }_{{T}_{C}}^{{T}_{H}} ( {α}_{p} - {α}_{n} ) d T \qquad ( 6 )$$

As represented by the expression (3), the figure of merit Z is inversely proportional to the thermal conductance K and the internal resistance R. Thus, it is effective to reduce the thermal conductance K and the internal resistance R in order to improve the figure of merit Z. The product of the thermal conductance K and the internal resistance R is represented by the following expression (7).

[Mathematical expression 7]

$$KR = {N}^{2} \frac{{κ}_{p}}{{σ}_{p}} ( 1 + \frac{1}{x {κ}_{pn}} + x {σ}_{pn} + \frac{{σ}_{pn}}{{κ}_{pn}} ) \qquad ( 7 )$$

Here, σₚₙ indicates a ratio of σₚ to σₙ (σₚ/σₙ), Kₚₙ indicates a ratio of Kₚ to Kₙ (Kₚ/Kₙ), and x indicates “(Aₚ/Aₙ)×(Lₙ/Lₚ)”. x indicates a parameter regarding a shape of the p-type thermoelectric conversion film 12 and the n-type thermoelectric conversion film 13. A value of x which minimizes the product KR of the thermal conductance K and the internal resistance R to maximize the figure of merit Z (x_{minKR}) is represented by the following expression (8).

[Mathematical expression 8]

$${x}_{min KR} = \frac{1}{\sqrt{{κ}_{pn} {σ}_{pn}}} \qquad ( 8 )$$

When this value is substituted into the expression (7), a minimum value of the product KR is obtained (expression (9)).

[Mathematical expression 9]

$${( KR )}_{min} = {N}^{2} \frac{{κ}_{p}}{{σ}_{p}} {( 1 + \sqrt{\frac{{σ}_{pn}}{{κ}_{pn}}} )}^{2} \qquad ( 9 )$$

Further, when the minimum value of the product KR is used, a maximum value of the figure of merit Z is obtained (expression (10)).

[Mathematical expression 10]

$${Z}_{max} = {[ \frac{\frac{1}{{T}_{H} - {T}_{C}} {\int }_{{T}_{C}}^{{T}_{H}} ( {a}_{p} - {α}_{n} ) d T}{( \sqrt{\frac{{κ}_{p}}{{σ}_{p}}} + \sqrt{\frac{{κ}_{n}}{{σ}_{n}}} )} ]}^{2} \qquad ( 10 )$$

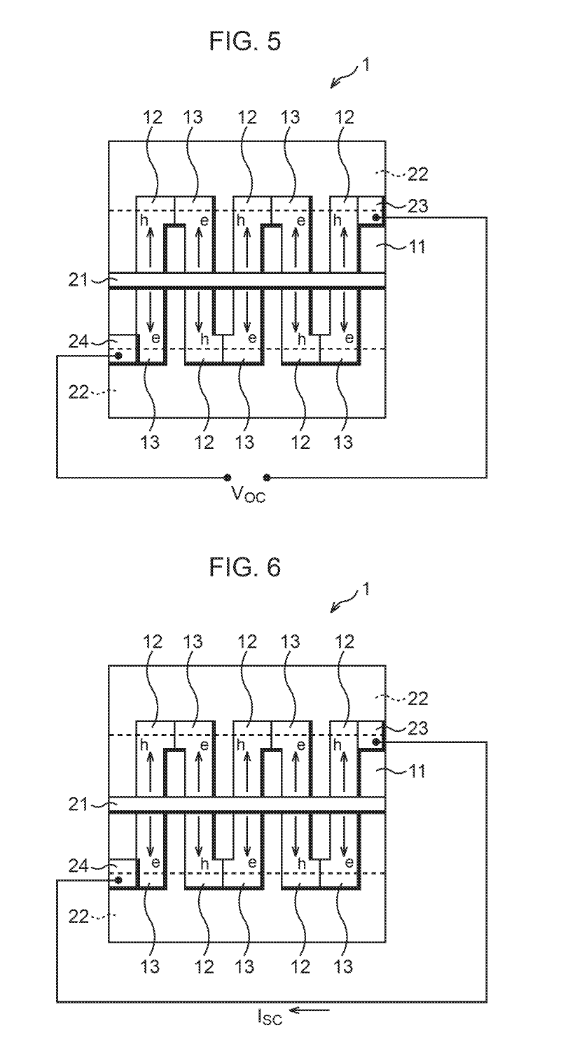

A voltage V_{OC} between terminals, when an open circuit illustrated in FIG. 5 is configured, is represented by an expression (11), and a current value I_{SC}, when a closed circuit illustrated in FIG. 6 is configured, is represented by an expression (12).

[Mathematical expression 11]

V_{OC}=NαΔT (11)

[Mathematical expression 12]

$${I}_{SC} = \frac{N αΔ T}{R} \qquad ( 12 )$$

Maximum power Pₘₐₓ is represented by “(V_{OC}/2)×(I_{SC}/2)”, so that from the expression (11) and the expression (12), the following expression (13) is derived.

[Mathematical expression 13]

$${P}_{max} = \frac{{( N α Δ T )}^{2}}{4 R} \qquad ( 13 )$$

As is apparent from the expression (5), since the internal resistance R is in proportion to the number N, it can be said that the maximum power Pₘₐₓ is in proportion to the number N, based on the expression (13). When an area in which the p-type thermoelectric conversion films 12 and the n-type thermoelectric conversion films 13 can be disposed is decided, the number N increases as a pattern of the p-type thermoelectric conversion films 12 and the n-type thermoelectric conversion films 13 is reduced, which leads to increase in the maximum power Pₘₐₓ, and a relation of an expression (14) is satisfied.

[Mathematical expression 14]

Pₘₐₓ∝(αΔT)²σ (14)

Therefore, in order to obtain high maximum power Pₘₐₓ, it is desirable to use a material with high effective Seebeck coefficient and high conductivity.

Next, electromotive force calculated based on the above-described mathematical expressions will be described based on two patterns. Here, a planar shape of the substrate 11 is a square with 15 mm×15 mm, a thickness of each of the p-type thermoelectric conversion film 12 and the n-type thermoelectric conversion film 13 is 1 μm, and a length in the series direction is 6 mm. In one pattern, by assuming that a metal mask is used, a line width of the p-type thermoelectric conversion films 12 and the n-type thermoelectric conversion films 13 is 80 μm, and the number of couples of the films 12 and 13 is 83. Results thereof are presented in Table 1. In the other pattern, by assuming that lithography is used, a line width of the p-type thermoelectric conversion films 12 and the n-type thermoelectric conversion films 13 is 20 μm, and the number of couples of the films 12 and 13 is 500. Results thereof are presented in Table 2. In Table 1 and Table 2, a La_{0.89}Sr_{0.11}CoO₃ film is used as the p-type thermoelectric conversion film 12, and a Sr_{0.95}La_{0.05}TiO₃ film is used as the n-type thermoelectric conversion film 13, in the condition A. In the condition B, a La_{0.89}Sr_{0.11}CoO₃ film is used as the p-type thermoelectric conversion film 12, and a film whose Seebeck coefficient is twice the Seebeck coefficient of the Sr_{0.95}La_{0.05}TiO₃ film is used as the n-type thermoelectric conversion film 13. In the condition C, a film whose Seebeck coefficient is twice the Seebeck coefficient of the La_{0.89}Sr_{0.11}CoO₃ film is used as the p-type thermoelectric conversion film 12, and a film whose Seebeck coefficient is twice the Seebeck coefficient of the Sr_{0.95}La_{0.05}TiO₃ film is used as the n-type thermoelectric conversion film 13. In the condition D, a film whose Seebeck coefficient is four times of the Seebeck coefficient of the La_{0.89}Sr_{0.11}CoO₃ film is used as the p-type thermoelectric conversion film 12, and a film whose Seebeck coefficient is four times of the Seebeck coefficient of the Sr_{0.95}La_{0.05}TiO₃ film is used as the n-type thermoelectric conversion film 13.

TABLE 1

| TEMPERATURE | | | | |
|---|---|---|---|---|
| GRADIENT | ELECTROMOTIVE FORCE (μW) | | | |
| (K) | CONDITION A | CONDITION B | CONDITION C | CONDITION D |
| 30 | 0.52 | 1.1 | 2.1 | 8.2 |
| 100 | 5.7 | 12.6 | 22.9 | 91.6 |

TABLE 2

| TEMPERATURE | | | | |
|---|---|---|---|---|
| GRADIENT | ELECTROMOTIVE FORCE (μW) | | | |
| (K) | CONDITION A | CONDITION B | CONDITION C | CONDITION D |
| 30 | 0.8 | 1.7 | 3.1 | 12.4 |
| 100 | 8.6 | 19.0 | 34.5 | 138.0 |

For example, electromotive force of about 0.3 mW is preferable for a thermometer, electromotive force of about 20 μW is preferable for a calculator, electromotive force of about 8 μW is preferable for a cardiac pacemaker, and electromotive force of about 3 μW to 5 μW is preferable for a watch. According to the above-described two patterns, it is possible to obtain electromotive force suitable for these applications, and according to the pattern which assumes the use of lithography, in particular, higher electromotive force can be obtained.

According to the above-described thermoelectric generator, since appropriate thermoelectric conversion films and heat transfer materials are included, it is possible to widen available application by enabling miniaturization.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A thermoelectric generator, comprising:
a substrate;
a thermoelectric conversion film on the substrate;
a thermally insulating film that covers the thermoelectric conversion film;
a first heat transfer material that transfers a first heat above the thermally insulating film to a first portion of the thermoelectric conversion film; and
a second heat transfer material that transfers a second heat below the substrate to a second portion of the thermoelectric conversion film, the second portion being separated from the first portion.

2. The thermoelectric generator according to claim 1, wherein the thermoelectric conversion film comprises a p-type thermoelectric conversion film and an n-type thermoelectric conversion film.

3. The thermoelectric generator according to claim 1, wherein the thermoelectric conversion film comprises p-type thermoelectric conversion films and n-type thermoelectric conversion films in couples, the p-type thermoelectric conversion films and the n-type thermoelectric conversion films being alternately and electrically connected in series.

4. The thermoelectric generator according to claim 3, wherein the p-type thermoelectric conversion film and the n-type thermoelectric conversion film in each of the couples are in contact with each other at a position right below the first heat transfer material.

5. A thermoelectric generator, comprising:
a substrate;
couples of p-type thermoelectric conversion films and n-type thermoelectric conversion films on the substrate;
a thermally insulating film that covers the p-type thermoelectric conversion films and the n-type thermoelectric conversion films;
a first heat transfer material that transfers a first heat above the thermally insulating film to first portions of the p-type thermoelectric conversion films and the n-type thermoelectric conversion films; and
a second heat transfer material that transfers a second heat below the substrate to second portions of the p-type thermoelectric conversion films and the n-type thermoelectric conversion films, each of the second portions being separated from each of the first portions, wherein:
the p-type thermoelectric conversion film and the n-type thermoelectric conversion film in each of the couple are in contact with each other at a position right below the first heat transfer material;
between the adjacent two couples, the p-type thermoelectric conversion film in one of the two couples and the n-type thermoelectric conversion film in the other one of the two couples are in contact with each other; and
the couples form a composite structure of the p-type thermoelectric conversion films and the n-type thermoelectric conversion films connected in series.

6. The thermoelectric generator according to claim 1, wherein the first heat transfer material contains Cu.

7. The thermoelectric generator according to claim 1, wherein the second heat transfer materials contain Cu.

8. The thermoelectric generator according to claim 2, wherein the p-type thermoelectric conversion film is a LaₐSr₁₋ₐCoO₃ film (0<a≦1), a La_{b}Ca_{1-b}CoO₃ (0<b≦1) film, or a LaMnO₃ film.

9. The thermoelectric generator according to claim 2, wherein the n-type thermoelectric conversion film is a Sr_{c}La_{1-c}TiO₃ film (0<c<1), or a Sr_{d}Nb_{1-d}TiO₃ film (0<d<1).

10. The thermoelectric generator according to claim 1, further comprising an electrically insulating film that covers the thermoelectric conversion film at a position under the thermally insulating film.

11. The thermoelectric generator according to claim 10, wherein the electrically insulating film is a SiO₂ film, a Si₃N₄ film, or a SrTiO₃ film.
